(19) United States
(12) Patent Application Publication
(10) Pub. No.: US 2002/0096623 A1
(43) Pub. Date: Jul. 25, 2002

(54) Apparatus and method for implementing resetting and reading-out in a cmos sensor

(75) Inventor: Chen-Ho Lee, Hsin-Chu City (TW)

Correspondence Address: LOWE HAUPTMAN GOPSTEIN GILMAN & BERNER, LLP, Suite 310, 1700 Diagonal Road, Alexandria, VA, 22314, US

(73) Assignee: UMAX DATA SYSTEMS INC.

(21) Appl. No.: 09/768,059

(22) Filed: Jan. 24, 2001

(51) Int. Cl. H01L 27/00

(52) U.S. Cl. 250/208.1

(57) ABSTRACT

Apparatus for simultaneously resetting and reading-out in a linear CMOS sensor and a plurality of photocells therein is provided to comprise enabling circuits that each is for simultaneously enabling a first switch device and a second switch device. The first switch device on a bypass of an access from the photocell to the second switch device and the second switch device on a access for the photocell to a common bus. A method for simultaneously resetting and reading-out in a linear CMOS sensor of a scanner comprises providing a plurality of photocells arranged in a row. The each photocell has an access to a common bus controlled by a corresponding first switch device and has a bypass of the access controlled by a corresponding second switch device. The second switch device of the first photocell is enabled to be reset, at the same time the first switch device of the second photocell that is next to the first photocell in the row is enabled to be read-out.

### BACKGROUND OF THE INVENTION

1. Field of the Invention

The invention relates to apparatus and a method for simultaneously resetting and reading-out in a CMOS sensor, and more particularly relates to apparatus and a method for a CMOS linear sensor that has no storage module, such as shift register, for reading-out.

2. Description of the Prior Art

Solid state image sensors are presently realized in two common forms: Charge Coupled Devices (CCDs) and MOS diode arrays. Both forms require specialized fabrication processes to suit them for image sensing and both forms also require substantial electronic circuits external to the sensing chip in order to drive the arrays and to process the output signal. A complete sensor subsystem therefore typically requires an assembly of many components with consequent implications of high production cost, power consumption and physical size.

Traditionally, solid state based scanners are realized charge-coupled devices (CCDS) as image capturing devices. Unfortunately, CCD technology is not compatible with standard DC processes for portable scanner development. In addition, CCDs use high voltage clock signals, implying correspondingly high power dissipation levels. Therefore, there is much interest in scanner using standard CMOS processes, which would promote integration and low power consumption.

Linear diode sensors are commonly based on a one dimensional row of photodiodes implemented as the reverse-biased semiconductor junctions of the type normally used to form the source and drain regions of MOS transistors. A high reverse bias is applied and the diode then is electrically isolated and exposed to light or other radiation to be detected. Incident radiation increases the reversed-bias leakage current to the diode and this current is effectively integrated on the reverse-bias capacitance of the isolated junction causing a reduction in the reverse-bias potential. The use of such techniques for conversion of radiation to electronic charge and potential is well known and practiced. In particular this technique is used in MOS linear diode type sensors. In these sensors a single MOS transistor controls access to the diode for the purpose of writing to the cell (that is, resetting to a high reverse-bias) and reading from it by connecting the diode to a bit-line (i.e. sense line) and thence ultimately to charge-sensing circuits which convert the charge stored within the cell to an output voltage.

Typically the linear, same as array, also can be accessed in scan-line format whereby the linear is read as consecutive pixels. This process is also commonly practiced and involves enabling a row of cells by a “word-line” which is connected in common to the access transistor gates of all cells in the row. Digital circuitry is used to generate and to drive the necessary pattern of word-line signals. Normally this circuitry may take the form of a shift register. As a word-line is enabled, the row of cells is connected to bit-lines and thereby to peripheral circuitry at the top of the linear. Further digital circuitry produces enabling signals that control analogue switching or sense circuitry to enable the signals on consecutive bit-lines to be connected to the output.

Shown in FIG. 1 is a column of an active sensor based on passive pixel cells 110. A passive pixel cell 110 has a very simple structure consisting of a photodiode PD with an associated capacitance Cd and a transistor switch MR. The photodiodes PD are connected to a common bus 120 through the switches MR1, MR2 . . . , MRx that are located inside each cell. The column bus 120 is coupled to the input of a charge amplifier (not shown), which provides a signal Vo that indicates the level of illumination collected by a one of the photodiodes PD.

However, for linear CMOS sensor, shift register built in the linear sensor raises the cost of a scanner. On the other hand, without shift register, a scanner has poor performance resulting from spending addition time of integration and read-out. Accordingly, it needs some resolutions under considering both cost-down and performance.

### SUMMARY OF THE INVENTION

It is an object of the present invention to provide an apparatus and a method for simultaneously implementing illumination and read-out steps of pixels in a CMOS sensor. The CMOS sensor has no memory devices, such as analog shift register and analog register, for temporarily saving image data.

It is another object of the present invention to provide an apparatus and a method for a scanner simultaneously illuminating and reading-out. The photocells in the scanner have same illumination periods with different reset starting time.

In the present invention, apparatus for simultaneously resetting and reading-out in a linear complementary metal-oxide-semiconductor sensor and a plurality of photocells therein is provided to comprise enabling circuits that each is for simultaneously enabling a first switch device and a second switch device. The first switch device on a bypass of an access from the photocell to the second switch device and the second switch device on an access for the photocell to a common bus. A method for simultaneously resetting and reading-out in a linear complementary metal-oxide-semiconductor sensor of a scanner comprises providing a plurality of photocells arranged in a row. The each photocell has an access to a common bus controlled by a corresponding first switch device and has a bypass of the access controlled by a corresponding second switch device. The second switch device of the first photocell is enabled to be reset, at the same time the first switch device of the second photocell that is next to the first photocell in the row is enabled to be read-out.

### BRIEF DESCRIPTION OF THE DRAWINGS

A better understanding of the invention may be derived by reading the following detailed description with reference to the accompanying drawing wherein;

FIG. 1 is a schematic diagram of a passive photodiode-based cell structure that is employed in prior art active pixel sensors;

FIG. 2 is a schematic diagram of a photo cell implemented in accordance with the present invention that can be employed in the pixel sensor of a scanner; and

FIG. 3 is a timing diagram showing voltage versus time plots of a subset of the signals employed in the preferred pixel sensor.

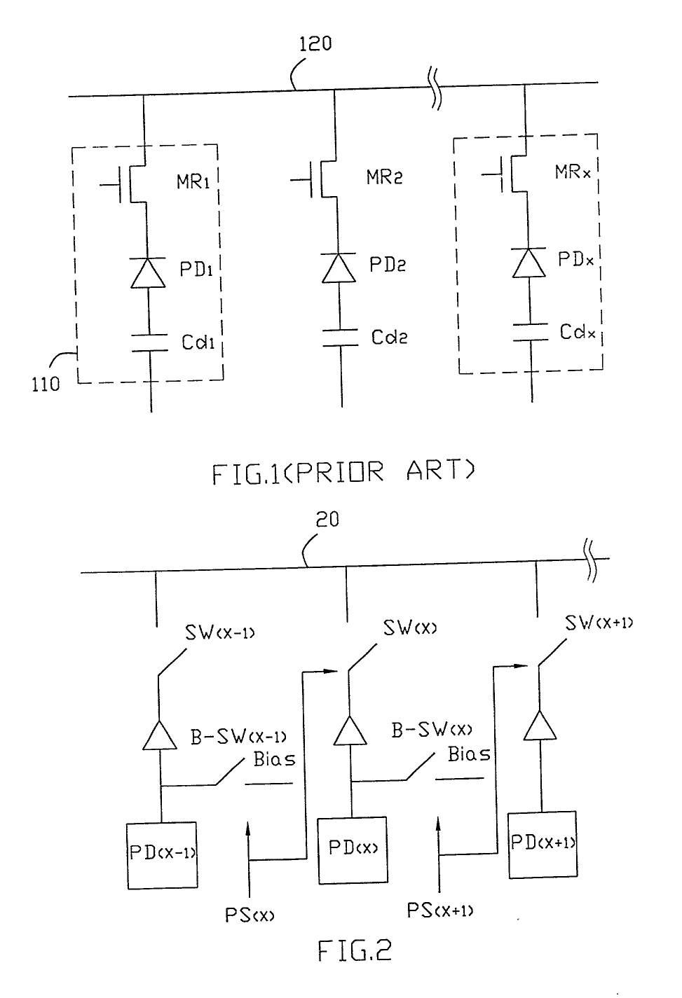

### DESCRIPTION OF THE PREFERRED EMBODIMENT

While the invention is described in terms of a single preferred embodiment, those skilled in the art will recognize that many devices described below can be altered as well as other substitutions with same function and can be freely made without departing from the spirit and scope of the invention.

Furthermore, there is shown a representative portion of a pixel sensor structure of the present invention in enlarged. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, apparatus for simultaneously resetting and reading-out in a linear CMOS sensor comprises photocells in a row of the linear CMOS sensor, first switch devices that each is on a first access connected to the corresponding photocell and coupled to a voltage supply circuit, and second switch devices that each is on a second access connected to the corresponding photocell and coupled to in common a bus. An enabling circuit is used for simultaneously enabling the first switch device of the first photocell and the second switch device of the second photocell that is next to the first photocell. A method for having same illumination periods with different starting times of exposure for a plurality of photocells in a linear CMOS sensor comprises providing photocells arranged in a row. The each photocell has an access to a common bus controlled by a corresponding first switch device, and a bypass of the access controlled by a corresponding second switch device. The second switch device of the first photocell is enabled to be reset, at the same time the first switch device of the second photocell that is next to the first photocell in the row is enabled to be readout.

FIG. 2 is a schematic diagram of photocells implemented in accordance with the present invention that can be employed in the pixel sensor of a scanner. Each preferred photocell of linear sensor includes a photodiode PD, a switch SW, a bias switch B-SW and a pixel select PS. All photocells are in common connected to a bus 20 that is coupled to external control circuits (not shown). All photodiodes PD(x−1), PD(x), PD(x+1) . . . , have their corresponding switches SW(x−1), SW(x), SW(x+1) . . . , bias switches B-SW(x−1), B-SW(x), B-SW(x+1) . . . and pixel selects PS(x−1), PS(x), PS(x+1) . . . . In the preferred embodiment, the pixel select PS(x) can simultaneously control switch SW(x) enabling an access between the photodiode PD(x) and the bus 20, and enable the prior bias switch B-SW(x−1). That is, the photodiode PD(x−1) is reset at the same time of reading-out for the photodiode PD(x) during the whole illumination period.

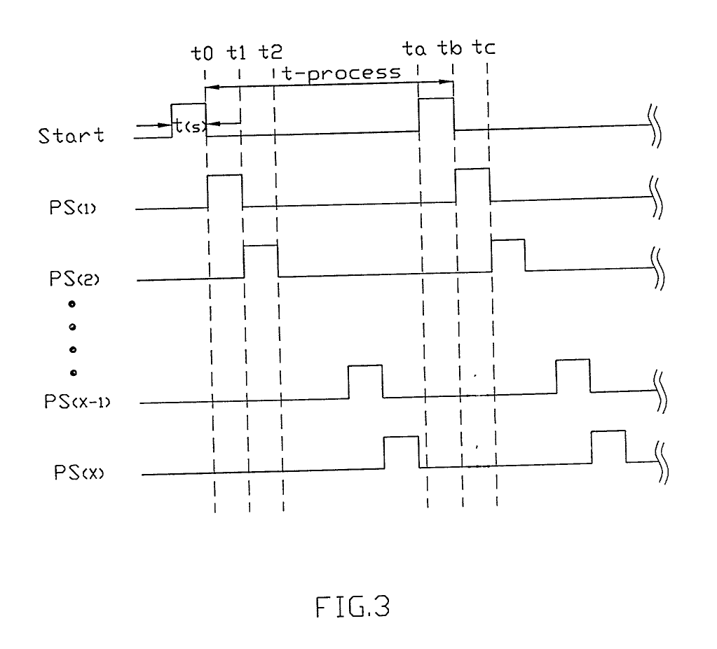

FIG. 3 is a timing diagram showing voltage versus time plots of a subset of the signals employed in the preferred linear pixel sensor. Start line is a control signal for reading starting at the photodiode PD(1), while pixel select line PS(1), PS(2), . . . PS(x) are individually control signals for reading corresponding photodiode PD(1), PD(2), . . . PD(x). A signal period t(s) is from time t1 to t0. A t-process is an integrating period starting at time t0 (i.e. voltage falling-down of a signal) and ending at time ta (i.e. voltage falling-down of next signal). Selected by the pixel select line PS(1), the photodiode PD(1) starts to be reset at time t0, finishes reset at time t1, and starts to be read at time tb. The accumulated illumination period for the photodiode PD(1) is t-process minus double t(s). Similarly, the photodiode PD(2) starts to be reset at time t1, finishes reset at time t2, and starts to be read at time tc. The accumulated illumination period for the photodiode PD(2) is also t-process minus double t(s). Accordingly, the accumulated illumination period for each photodiode in the linear sensor is same as each another. Furthermore, the reset step of the photodiode is implemented at the same time of reading-out step of the neighbor photodiode.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. Apparatus for simultaneously resetting and reading-out in a linear complementary metal-oxide-semiconductor sensor and a plurality of photocells therein, said apparatus comprising:
a plurality of enabling circuits, each said enabling circuit for simultaneously enabling a first switch device and a second switch device, said first switch device on a bypass of a access from said photocell to said second switch device and said second switch device on an access for said photocell to a common bus.

2. The apparatus of claim 1, wherein said each enabling circuit is corresponding said photocell.

3. The apparatus of claim 1, wherein said first switch is corresponding a first photocell, and while said second switch is corresponding a second photocell that is next to said first photocell in a row of said linear complementary metal-oxide-semiconductor sensor.

4. The apparatus of claim 1, wherein said each enabling circuit comprises a corresponding pixel select line coupled to an external control circuit.

5. Apparatus for simultaneously resetting and reading-out in a linear complementary metal-oxide-semiconductor sensor, said apparatus comprising:
a plurality of photocells in a row of said linear complementary metal-oxide-semiconductor sensor;
a plurality of first switch devices, each said first switch device on a first access connected to said corresponding photocell and coupled to a voltage supply circuit;
a plurality of second switch devices, each said second switch device a second access connected to said corresponding photocell and coupled to in common a bus; and
a plurality of enabling circuits, each said enabling circuit for simultaneously enabling said first switch device of said first photocell and said second switch device of said second photocell that is next to said first photocell.

6. The apparatus of claim 5, wherein each said enabling circuit comprises a pixel select line coupled to an external control circuit.

7. The apparatus of claim 5, wherein said photocells comprise a plurality of photodiodes.

8. The apparatus of claim 5, wherein said voltage supply circuit is for supplying a bias voltage.

9. A method for simultaneously resetting and reading-out in a linear complementary metal-oxide-semiconductor sensor of a scanner, said method comprising:
providing a plurality of photocells arranged in a row, each said photocell having an access to a common bus controlled by a corresponding first switch device, and having a bypass of said access controlled by a corresponding second switch device; and
simultaneously enabling said second switch device of said first photocell and said first switch device of said second photocell that is next to said first photocell in said row.

10. The method according to claim 9, wherein said bypass is further coupled to a bias voltage supply circuit.

11. The method according to claim 9, wherein said enabling step is implemented by a plurality of corresponding control circuits comprising a plurality of pixel select lines.

12. The method according to claim 9, wherein said enabling step comprises:
resetting said first photocell; and
reading-out said second photocell.

13. The me thod according to claim 9 further comprising consequently illuminating said photocells in said row of linear sensor.

14. The method according to claim 9, wherein said photocells comprise a plurality of photodiodes.

15. A method for having same illumination periods with different starting times of exposure for a plurality of photocells in a linear complementary metal-oxide-semiconductor sensor, said method comprising:
providing a plurality of photocells arranged in a row, each said photocell having an access to a common bus controlled by a corresponding first switch device, and having a bypass of said access controlled by a corresponding second switch device; and
simultaneously enabling said second switch device of said first photocell and said first switch device of said second photocell that is next to said first photocell in said row.

16. The method according to claim 15, wherein said illumination period represents a period starting at the moment said photocell ending to be reset, and ending at the moment said photocell beginning to be read-out.

17. The method according to claim 15, wherein said enabling step comprises:
resetting said first photocell; and
reading-out said second photocell.

18. The method according to claim 15 further comprising consequently illuminating said photocells in said row of linear sensor.

19. The method according to claim 15, wherein said photocells comprise a plurality of photodiodes.
